(19) United States
(12) Patent Application Publication
(10) Pub. No.: US 2002/0081771 A1
(43) Pub. Date: Jun. 27, 2002

(54) Flip chip process

(76) Inventors: Yi-Chuan Ding, Kaohsiung (TW); In-De Ou, Kaohsiung (TW); Kun-Ching Chen, Tainan (TW); Yung-I Yeh, Kaohsiung (TW)

Correspondence Address: J.C. Patents, Inc., 4 Venture, Suite 250, Irvine, CA, 92618, US

(21) Appl. No.: 09/900,054

(22) Filed: Jul. 6, 2001

(30) Foreign Application Priority Data
Dec. 22, 2000 (TW) 89127631

(51) Int. Cl. H01L 21/44; H01L 21/48; H01L 21/50

(52) U.S. Cl. 438/108; 438/613

(57) ABSTRACT

In a flip chip process, a wafer is provided with a plurality of chips therein. Each chip has an active surface on which are formed a plurality of bonding pads. A bump is formed on each bonding pad. A plurality of substrates respectively includes at least a package unit, wherein each package unit has a plurality of contact pads. The substrates are respectively mounted onto the wafer such that each package unit corresponds to one chip and the contact pads of the package unit are respectively connected to the corresponding bumps, wherein two neighboring substrates are separated by a gap. An underfill material fills between the wafer and the substrates, the underfill material being introduced through the gaps between the substrates and from the boundary of the wafer. The underfill material then is solidified. The substrates and the wafer are diced to form individualized packages.

### CROSS-REFERENCE TO RELATED APPLICATION

This application claims the priority benefit of Taiwan application serial no. 89127631, filed Dec. 22, 2000.

### BACKGROUND OF THE INVENTION

1. Field of the Invention

The present invention relates to a flip chip process. More particularly, the present invention relates to a wafer level flip chip packaging process.

2. Description of the Related Art

As the era of information technology progresses, the transmission and processing of information and documents are extensively accomplished by means of electronic products. Accompanying the progress of technology, many commercial products with more convenient features are promoted, as mobile phones, computers, audio-video articles, while the emphasis is made to miniaturization.

In this present context, integrated circuit packaging processes, accompanying the development of integrated circuit manufacturing, emphasizes on high density products. Consequently, many high pin-count packaging structures and high-density chip scale packaging (CSP) structures are developed. Flip chip technology is extensively employed in chip scale packaging (CSP). “Flip chip” principle consists of mounting and connecting directly the chip to the carrier via a plurality of bumps, which advantageously shortens the electrical path and reduces the surface area of the package. In order to improve the throughput and simplify the packaging processes, wafer-level packaging is also extensively developed. Used in wafer-level packaging, flip chip technology can substantially improve the throughput and the efficiency of the packaging processes and reduce the manufacturing time.

Referring to FIG. 1 and FIG. 2, cross-sectional views schematically illustrate a conventional flip chip packaging process. As shown in FIG. 1, in the conventional flip chip packaging process, a surface 102 of a chip 100 is conventionally provided with a plurality of bonding pads 104. A bump 106 is formed on each bonding pad 104. A surface 152 of a substrate 150 is provided with a plurality of contact pads 154, wherein each of the contact pads 154 respectively corresponds to each of the bonding pads 104 of the chip 100. The bumps 106 of the chip 100 are aligned and put in contact with the contact pads 154 of the substrate 150. A reflow process then is performed to connect the chip 100 to the substrate 150 via the bumps 106. After reflow process, the reflowed bumps 106 are referred to as a plurality of connecting bumps 108 that connects the chip 100 to the substrate 150. An underfill material 180 is filled between the chip 100 and the substrate 150, wherein the underfill material 180 encapsulates the connecting bumps 108. The underfill material 180 then is solidified.

In the above conventional flip chip process, the wafer on which are formed the chips 100 usually has to be diced to obtain individualized chips. Then, each of the chips 100 is flipped such that the bumps 106 are downside to connect onto the substrate. Such a conventional process is substantially time-consuming, reduces the throughput and lowers the efficiency of the packaging process.

### SUMMARY OF THE INVENTION

An aspect of the present invention therefore is to provide a flip chip packaging process that can substantially improve the throughput and the efficiency of the production.

To attain at least the foregoing objectives, the present invention provides a flip chip packaging process that comprises the following steps. A wafer is provided with a plurality of chips, wherein an active surface of each chip has a plurality of bonding pads. A plurality of bumps are respectively formed on the bonding pads of the chips. A plurality of substrates respectively include at least a package unit therein, wherein each package unit further includes a plurality of contact pads. The substrates are respectively mounted on the wafer such that each package unit corresponds to one chip and the contact pads of the package unit are respectively connected to the bumps attached to the chip. Mounted onto the wafer, two neighboring substrates are separated by a gap. An underfill material is introduced through the gaps between the substrates and from the boundary of the wafer to fill the space between the wafer and the substrates. The underfill material then is solidified. A dicing process is performed to separate the chips and package units of the substrates into a plurality of individual flip chip packages.

To attain at least the above objectives, the present invention, according to another embodiment, provides a flip chip process that comprises the following steps. A wafer is provided with a plurality of chips therein, wherein an active surface of each chip comprises a plurality of bonding pads thereon. A plurality of substrates further respectively include at least a package unit, wherein the surface of each package unit includes a plurality of contact pads thereon. A bump is respectively formed the contact pads of the package units. The substrates are respectively mounted onto the wafer such that each package unit corresponds to one chip and the bumps attached to the package unit are respectively connected to the bonding pads of the chip. Mounted on the wafer, two neighboring substrates are separated by a gap. An underfill material is introduced through the gaps between the substrates and from the boundary of the wafer to fill the space between the wafer and the substrates. The underfill material then is solidified. A dicing process is performed to separate the chips and package units of the substrates into a plurality of individual flip chip packages.

The substrate includes, for example, at least a patterned conductive layer laminated with at least an insulating layer. The surface of each package unit is smaller or equal to the surface of the corresponding chip.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 and FIG. 2 are cross-sectional views illustrating the conventional flip chip packaging process;

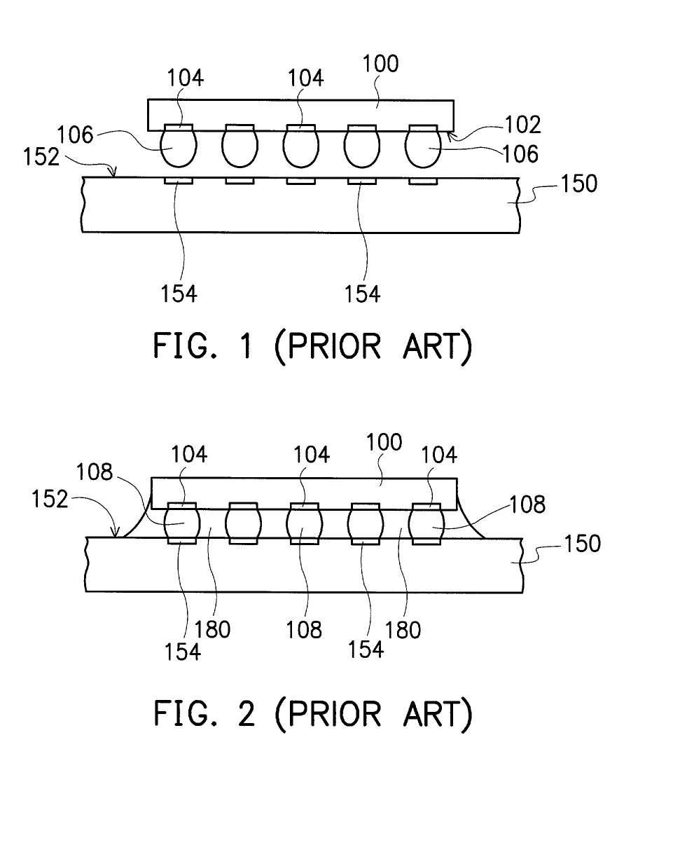

FIG. 3, FIG. 4 and FIG. 5 are cross-sectional views showing different stages in a flip chip packaging process according to an embodiment of the invention;

FIG. 6 is a cross-sectional view illustrating a flip chip packaging process according to a second embodiment of the invention; and

FIG. 7 is a cross-sectional view showing an alternative example of the flip chip packaging process of the invention.

### DESCRIPTION OF THE PREFERRED EMBODIMENTS

The features and advantages of the present invention will be more clearly understood from the following detailed description taken in conjunction with the accompanying drawings. The following detailed description is only illustrative and not limiting.

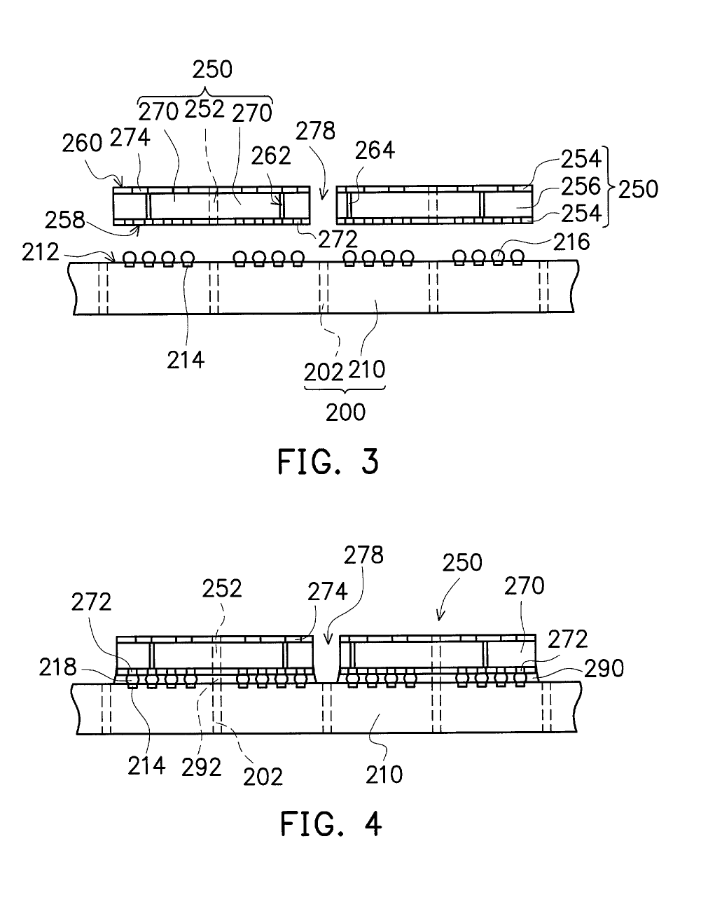

Referring now to FIG. 3 to FIG. 5, various cross-sectional views schematically illustrate various stages in a flip chip packaging process according to a first embodiment of the invention. A wafer 200 is provided with a plurality of chips 210 and a plurality of wafer scribe lines 202 thereon. The wafer scribe lines 202 space apart the chips 210 from one another. An active surface 212 of each chip 210 includes a plurality of bonding pads 214 thereon. A bump 216 is respectively formed on the bonding pads 214 of the chips 210. The bumps 216 are made of conductive material such as tin-lead alloy, gold or conductive polymer, for example.

A plurality of substrates 250 are provided with at least a package unit 270 therein. The substrates 250 can be fabricated from, for example, a plurality of patterned conductive layers 254 alternately laminated with insulating layers 256. The insulating layer 256 can be made of, for example, FR-4, FR-5, bismaleimide-triazine (BT), polyimide, epoxy, or ceramic. Alternately, the substrates 250 can be a singlelayer substrate comprising a single patterned conductive layer and a single insulating layer. In the present description, the substrates 250 are described as exemplary multilayer substrates.

The package units 270 are spaced apart from one another by a plurality of substrate scribe lines 252. Each package unit 270 has a front surface 260 and a back surface 258. A plurality of contact pads 272 are formed on the back surface 258 and a plurality of outward contact pads 274 are formed on the front surface 260 of each package unit 270. A plurality of through holes 262 formed in the insulating layer 256 of each package unit 270 are filled with a conductive material 264 such that the contact pads 272 are respectively connected to the outward contact pads 274 through the vias (262+264) thus formed. The substrates 250 are disposed above the wafer 200, wherein the back surface 258 of the package units 270 is smaller or equal to the surface 212 of the chips 210.

Referring to FIG. 3 and FIG. 4, cross-sectional views schematically illustrate the electrical connection process. The substrates 250 are respectively mounted onto the wafer 200 such that the contact pads 272 of each package unit 270 are respectively aligned and in contact with the bumps 216 attached to each chip 210, wherein a gap 278 separates two neighboring substrates 250. A reflow process then is performed to connect the package units 270 to the chips 210. Reference numeral 218 now refers to a plurality of connecting bumps after the bumps 216 are reflowed. After the reflowing process, flux residues (not shown) conventionally used during the reflowing may remain on the active surface 212 of the chips 210. Solvents thus are conventionally used to clean the active surface 212.

Once the substrates 250 are arranged on the chips 210, the space between the wafer 200 and the substrates 250 are filled with an underfill material 290 introduced through the gaps 278 between the substrates 250 and from the boundary of the wafer 200. The underfill material 290 can be introduced under liquid form, for example, to obtain uniform distribution and prevent air voids, and subsequently solidified through a thermal process. The thus formed underfill material 290 encapsulates the connecting bumps 218. Reference numeral 292 represents the profile extension of substrate scribe lines 252 in the underfill material 290.

Referring to FIG. 4 and FIG. 5, the wafer 200 and substrates 250 are diced through the scribe lines 202, 252 and 292 to singularize and form individualized flip chip packages.

A plurality of solder balls 280 are respectively formed on the outward contact pads 274 of the package units 270. The solder balls 280 provide the individual flip chip packages with electrical connection to external devices.

As described above with reference to FIG. 3 through FIG. 5, the package units 270 are formed in specifically designed substrates 250. Thus, all the package units 270 can be simultaneously arranged onto the chips 210 to connect the bonding pads 214 of the chips to the contact pads 272 of the package units 270 through the bumps. The substrates 250 and the wafer 200 mounted to each other then can be diced to form the individual flip chip packages. The time of processing thus can be shortened and the throughput improved. Moreover, the surface of the substrates 250 is relatively small in the invention such that the underfill material 290 can be uniformly filled, and the mounting of the wafer 200 and the substrates 250 can be facilitated. As a result, the workability and efficiency of the flip chip process are improved.

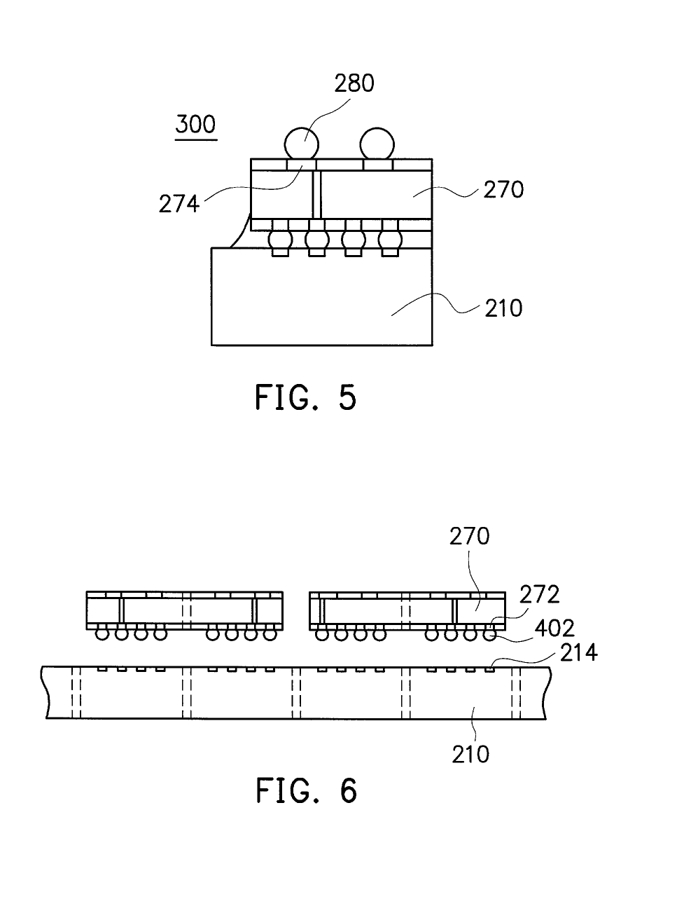

In the previous description of the invention, the bumps are formed on the bonding pads of the chips. However, the bumps 402 can be first formed on the contact pads 272 of the package units 270 as shown in FIG. 6. A reflow process then is performed with the bumps 402 attached to the package units 270 and put in contact with the bonding pads of the chips.

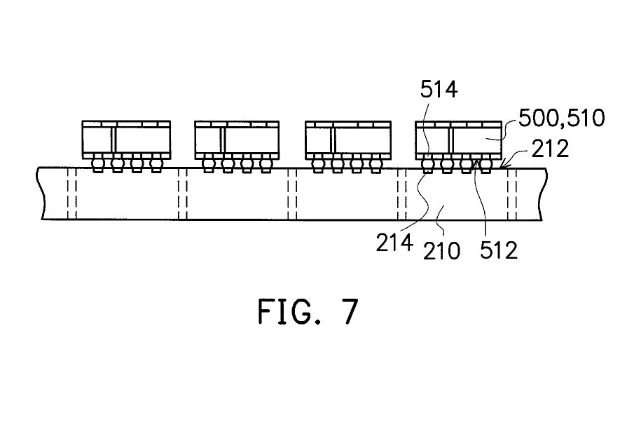

In the previous description of the present invention, a plurality of package units are integrated in a single substrate. However, each substrate 500 can have, for example, a single package unit 510 therein, wherein the back surface 512 of the package unit 510 is smaller than the active surface 212 of the corresponding chip 210, as shown in FIG. 7.

In conclusion, the foregoing description of embodiments and examples of the present invention reveals at least the following advantages. Since the package units, integrated into a plurality of substrates, are simultaneously bonded and connected to the chips and, subsequently, the substrates and the wafer are together singly diced, the time of processing thus can be shortened and the throughput improved. Moreover, the wafer-level packaging of the present invention uses a plurality of substrates that respectively include a plurality of package units, which differs from the conventional wafer-level packaging method in which a single substrate is bonded and connected to a single chip. As a result, the efficiency of the wafer-level packaging process can be substantially improved, and the filling of the underfill material, problematic in the prior art, can be made more workable and efficient.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A flip chip packaging process comprising:
providing a wafer having a plurality of chips formed thereon, wherein each chip has an active surface provided with a plurality of bonding pads;
forming a bump on each bonding pad;
providing a plurality of substrates, wherein each substrate includes at least a package unit, each package unit having a plurality of contact pads thereon;
respectively mounting the substrates onto the wafer such that each package unit corresponds to each chip and the contact pads are respectively connected to the corresponding bumps, wherein two neighboring substrates are separated by a gap;
filling an underfill material between the substrates and the wafer, the underfill material being introduced through the gaps between the substrates and from the boundary of the wafer;
solidifying the underfill material; and
dicing the wafer and the substrates to form a plurality of individualized packages, each individualized package including one chip and one package unit.

2. The flip chip packaging process of claim 1, wherein each substrate includes at least a patterned conductive layer alternately laminated with at least an insulating layer.

3. The flip chip packaging process of claim 1, wherein each substrate includes a plurality of patterned conductive layers alternately laminated with a plurality of insulating layers.

4. The flip chip packaging process of claim 2, wherein the material of the insulating layer is FR-4, FR-5, bismaleimide triazine (BT), polyimide, or materials composite of epoxy and ceramic.

5. The flip chip packaging process of claim 1, wherein the material of the bumps is tin-lead alloy, gold or conductive polymer.

6. The flip chip packaging process of claim 1, wherein the surface of each of package unit is smaller or equal to the active surface of the corresponding chip.

7. A flip chip packaging process comprising:
providing a wafer having a plurality of chips formed thereon, wherein each chip has an active surface provided with a plurality of bonding pads;
providing a plurality of substrates, wherein each substrate includes at least a package unit, the package unit having a plurality of contact pads;
forming a bump on each contact pad;
respectively mounting the substrates onto the wafer such that each package unit corresponds to one chip and the bonding pads are respectively connected to the corresponding bumps, wherein two neighboring substrates are separated by a gap;
filling an underfill material between the substrates and the wafer, wherein the underfill material is introduced through the gaps between the substrates and from the boundary of the wafer;
solidifying the underfill material; and
dicing the wafer and the substrates to form a plurality of individualized packages, each individualized package including one package unit and one chip.

8. The flip chip packaging process of claim 7, wherein each substrate includes by at least a patterned conductive layer alternately laminated with at least an insulating layer.

9. The flip chip packaging process of claim 7, wherein each substrate includes a plurality of patterned conductive layers alternately laminated with a plurality of insulating layers.

10. The flip chip packaging process of claim 8, wherein the material of the insulating layer is FR-4, FR-5, bismaleimide triazine (BT), polyimide, or materials composite of epoxy and ceramic.

11. The flip chip packaging process of claim 7, wherein the material of the bumps is tin-lead alloy, gold or conductive polymer.

12. The flip chip packaging process of claim 7, wherein the surface of each package unit is smaller or equal to the active surface of the corresponding chip.
